(19) United States
(12) Patent Application Publication
(10) Pub. No.: US 2014/0034588 A1
(43) Pub. Date: Feb. 6, 2014

(54) FRAME WITH CONNECTION MEMBER FOR CONNECTING FLANGES OF THE FRAME

(71) Applicant: WEI WANG, Shenzhen City (CN)

(72) Inventor: WEI WANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/586,808

(22) Filed: Aug. 15, 2012

(30) Foreign Application Priority Data
Aug. 1, 2012 (CN) 2012102701153

(51) Int. Cl. H01L 23/32

(52) U.S. Cl. 211/41.1

(57) ABSTRACT

A frame includes two flanges and a connection member. Each flange includes an outer plate and an inner plate parallel to the outer plate. A first sidewall and a second sidewall extend from the outside plate to be connected to the inner, parallel to each other. The outer side plate, the inner side plate, and the first and second sidewalls together bound a receiving space. The connection member includes a first connecting plate engaged in the receiving space of one of the flanges, and a second connecting plate engaged in the receiving space of the other flange. A number of parallel grooves are defined in each of the first and second connecting plates. A number of blocks extend from an inner side of the inner side plate to engage in the corresponding grooves.

### BACKGROUND

1. Technical Field

The present disclosure relates to frames and, particularly, to a frame including a connection member for connecting two adjacent flanges of the frame.

2. Description of Related Art

A photovoltaic module frame always includes four flanges connected end to end. Every two adjacent flanges are connected to each other through an L-shaped connection member. The connection member is always connected to the flanges through screwing or riveting, which is inconvenient.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an embodiment of a part of a frame with a connection member.

FIG. 2 is an exploded, isometric view of the frame of FIG. 1.

FIG. 3 is a cross-sectional view taken along the line of III-III of FIG. 1.

### DETAILED DESCRIPTION

The disclosure, including the accompanying drawings in which like references indicate similar elements, is illustrated by way of examples and not by way of limitation. It should be noted that references to “an” or “one” embodiment in this disclosure are not necessarily to the same embodiment, and such references mean at least one.

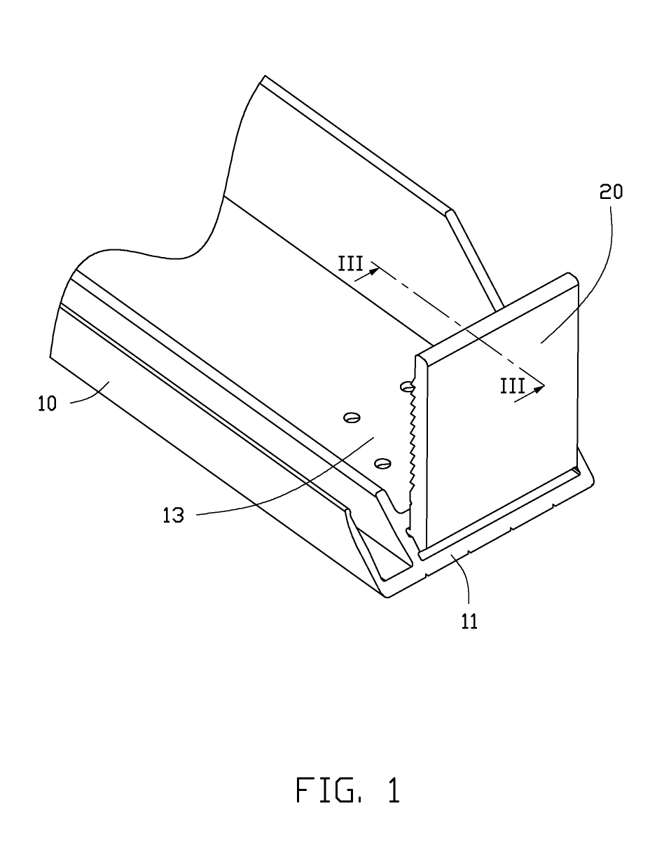

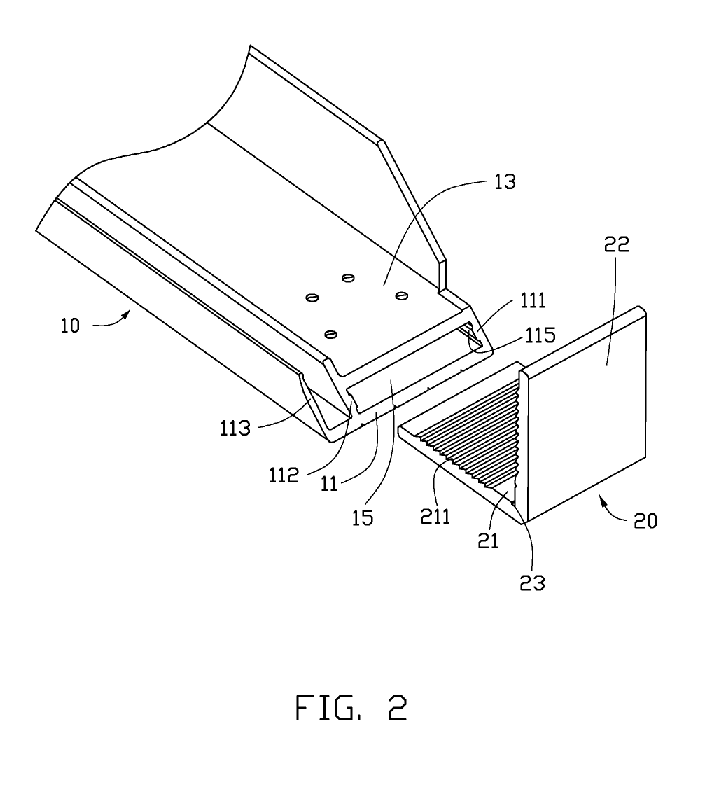

Referring to FIG. 1 and FIG. 2, an embodiment of a frame for mounting a photovoltaic module (not shown) is illustrated. The frame includes two flanges 10 and a connection member 20. In the figures, only one flange 10 is shown. In one embodiment, the flanges 10 are made of aluminum.

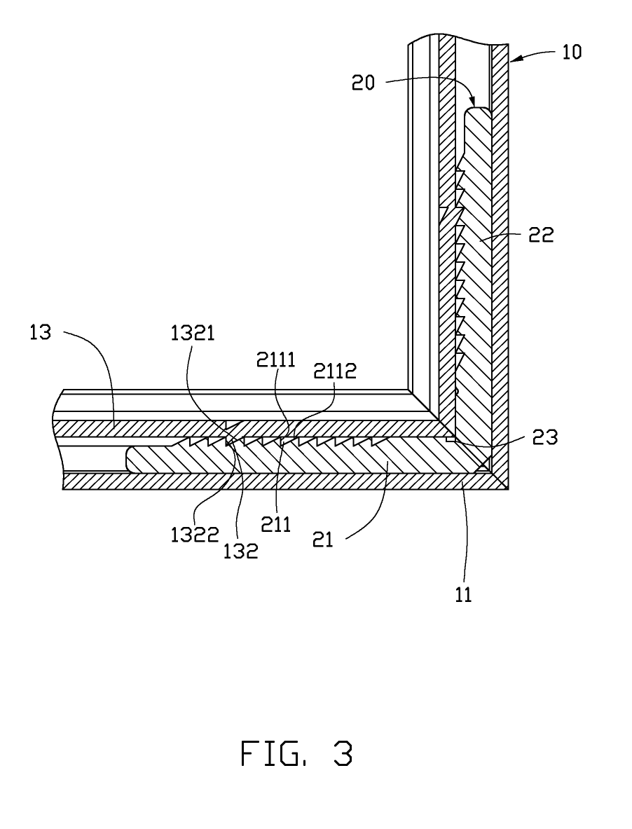

Each flange 10 includes an outer plate 11, an inner plate 13 parallel to the outer plate 11, a first sidewall 111 connected between first sides of the outer plate 11 and the inner plate 13, a second sidewall 112 connected between second sides of the outer plate 11 and the inner plate 13, and a third sidewall 113 extending from an edge of the outer plate 11 adjacent to the second side of the outer plate 11 and parallel to the second sidewall 112. The outer plate 11, the inner plate 13, the first sidewall 111, and the second sidewall 112 together bound a receiving space 15. The second sidewall 112, the third sidewall 113, and the outer plate 11 together bound a channel for receiving a side of the photovoltaic module. An elongated raised portion 115 extends into the receiving space 15 from an inner surface of each of the first sidewall 111 and the second sidewall 112. Four blocks 132 extend into the receiving space 15 from an inner surface of the inner plate 13, as shown in FIG. 3. The blocks 132 are arranged in an isosceles trapezoid, and adjacent to an end of the flange 10. Each block 132 includes a first slope 1321 facing the end of the flange 10, and a second slope 1322 opposite to the first slope 1321. The angle between the first slope 1321 and the inner surface of the inner plate 13 is greater than the angle between the second slope 1322 and the inner surface of the inner plate 13.

The connection member 20 is substantially L shaped, and includes a first connecting plate 21 and a second connecting plate 22 perpendicularly extending from an end of the first connecting plate 21. A junction 23 is formed between the first connecting plate 21 and the second connecting plate 22. The first connecting plate 21 and the second connecting plate 22 each define a plurality of substantially V-shaped grooves 211 parallel to the junction 23. Each groove 211 of each of the first and second connecting plates 21 and 22 includes a first wall 2111 facing the junction 23 and substantially parallel to the other one of the first and second connecting plates 21 and 22, and a slanting second wall 2112 opposite to the junction 23 and acutely connected to the first wall 2112. In the embodiment, the connection member 20 is made of aluminum.

Referring to FIG. 3, in assembly, the first connecting plate 21 is put into the receiving space 15 from the end of one flange 10, until an edge of the inner plate 13 at the end of the flange 10 engages with the second connecting plate 22. The raised portions 115 abut two opposite edges of the first connecting plate 21. Two blocks 132 are engaged in one of the grooves 211 of the first connecting plate 21, the other two blocks 132 are engaged in another groove 211 of the first connecting plate 21. The second walls 2112 mating with the first slopes 1321 are beneficial to put the first connecting plate 21 into the receiving space 15. The first walls 2111 abut the second slopes 1322 to prevent the first connecting plate 21 from being released out of the receiving space 15. Therefore, the first connecting plate 21 is easy to be put in, but hard to be pulled out of the receiving space 15. The second connecting plate 22 is used for connecting the other flange 10 in a same way. The channel bounded by the second sidewall 112, the third sidewall 113, and the outer plate 11 of the other flange 10 can receive an adjacent side of the photovoltaic module.

When the first connecting plate 21 is being put into the receiving space 15, the blocks 132 notch the first connecting plate 21 along a direction perpendicular to the grooves 211.

In the embodiment, the blocks 132 are formed by stamping before the first and second connecting plates 21 and 22 are received in the receiving spaces 15. In an alternative embodiment, the blocks 132 can be formed by stamping after the first and second connecting plates 21 and 22 are received in the receiving spaces 15. The blocks 132 may be arranged in another shape, such as rectangle. The blocks 132 can be formed to be different heights to supply different connection forces between the flanges 10.

In order to test the connection forces between the flanges 10 of the frame, an universal material testing machine is employed under 23±5° C. ambient temperature, and the blocks 132 being formed by stamping after the first and second connecting plates 21 and 22 are received in the receiving spaces 15. The test results are shown in the below table:

| | Arrangement | Height | Connection force |
|---|---|---|---|
| Number | of the blocks 132 | of the blocks (mm) | (N) |
| 1 | isosceles trapezoid | 1.3 | 1876.7 |
| 2 | isosceles trapezoid | 1.2 | 1690.3 |
| 3 | rectangle | 1.3 | 1292.0 |
| 4 | rectangle | 1.0 | 602.3 |

According to the above test results, the connection member 20 can supply enough connection force to meet the need. When the arrangement of the blocks 132 is isosceles trapezoid, the connection member 20 can supply more connection force than the rectangle arrangement of the blocks 132. The connection member 10 can supply more connection force when the height of the blocks 132 becomes greater.

It is to be understood, however, that even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A frame, comprising:
two flanges each comprising an outer plate, an inner plate parallel to the outer plate, a first sidewall connected between first sides of the outer and inner plates, and a second sidewall connected between second sides of the outer and inner plates, wherein the first sidewall, the second sidewall, the outer plate, and the inner plate together bound a receiving space; and
a connection member comprising a first connecting plate engaged in the receiving space of one of the two flanges, and a second connecting plate extending from the first connecting plate and engaged in the receiving space of the other flange;
wherein each of the first and second connecting plates defines a plurality of grooves, a plurality of blocks is formed from an inner surface of the inner plate of each flange and detachably engaged in the corresponding grooves of a corresponding one of the first and second connecting plates.

2. The frame of claim 1, wherein each block comprises a first slope and a second slope opposite to the first slope, each groove comprises a first wall and a second wall, the first wall abuts the second slope to prevent the corresponding one of the first and second connecting plates from releasing out of the corresponding receiving space.

3. The frame of claim 2, wherein an angle between the first slope and the inner surface of the inner plate is greater than an angle between the second slope and the inner surface of the inner plate.

4. The frame of claim 1, wherein the number of the blocks is four, and the four blocks are arranged in isosceles trapezoid.

5. The frame of claim 1, wherein an inner surface of each of the first sidewall and the second sidewall comprises a raised portion, the raised portions of the first and second sidewalls abut two opposite edges of the corresponding one of the first and second connecting plates.

6. The frame of claim 1, wherein the second connecting plate is angled with the second connecting plate, the grooves are parallel to a junction of the first and second connecting plates.

7. The frame of claim 1, wherein the blocks are formed by stamping before the first and second connecting plates are received in the receiving spaces.

8. The frame of claim 1, wherein the blocks are formed by stamping after the first and second connecting plates are received in the receiving spaces.
